(19) United States
(12) Patent Application Publication
(10) Pub. No.: US 2015/0273737 A1
(43) Pub. Date: Oct. 1, 2015

(54) FLEXIBLE AND STRETCHABLE GRAPHENE FILM AND PREPARING METHOD OF THE SAME

(71) Applicant: National Taiwan University, Taipei (TW)

(72) Inventors: Yang-Fang CHEN, Taipei (TW); Ying-Chih LAI, Taipei City (TW)

(73) Assignee: National Taiwan University, Taipei (TW)

(21) Appl. No.: 14/242,118

(22) Filed: Apr. 1, 2014

(51) Int. Cl. B29C 41/22; C23C 16/26; B29C 41/04; B29D 7/01; H01B 1/20; H01B 3/44

(52) U.S. Cl. CPC B29C 41/22; H01B 1/20; H01B 3/447; B29C 41/045; B29D 7/01; C23C 16/26; B29K 2281/00

(57) ABSTRACT

The present invention relates to a flexible and stretchable graphene film, comprising a graphene layer and a functional layer formed on the graphene layer; a preparing method of the graphene film. The present invention further relates to a method of producing a graphene film, comprising: (a) providing a carrier, and a graphene layer is formed on the surface of the carrier, (b) forming a functional layer containing an insulating polymer and a conductive material on a top portion of the graphene film; and (c) dissolving the carrier by an etchant. Without harsh synthesis and complicated fabrication steps, the graphene film of the present invention is able to transfer onto various substrates, and is largely beneficial to various electronic applications.

### BACKGROUND OF THE INVENTION

1. Field of the Invention

The present invention relates to a flexible and stretchable graphene film, preparing method thereof, and use of the flexible and stretchable graphene film.

2. Description of the Related Art

Stretchable, flexible or wearable electronics have been developed rapidly and led the electronic applications to a new class. Such emerging devices have attracted keen interest due to their tremendous potential in a wide field of future applications, such as wearable computer, highly flexible paper displays with stretchability, artificial electronic skin, biomedical applications for health monitoring, and biological actuation. Future “intelligent” stretchable or flexible electronic modules will require integrating multiple crucial electronic devices, such as logic memory, power supply, and display onto an elastic polymeric substrate. So far, successful progress for stretchable electronics has been reported on different core electronics such as transistors, light-emitting diodes (LEDs), sensors, antenna, solar cells and batteries. A crucial challenge for those electronics is how to fabricate and integrate multiple flexible and stretchable electronic devices onto a polymeric or nonconventional substrate. This hurdle arises from the fact that those nonconventional substrates are suffered from difficult handling requirements and poor tolerance for high temperature and chemical processing.

Recently, graphene, one of the thinnest known materials, has gained great attention of many researchers and companies because of its exceptional physical and electrical properties. The excellent mechanical flexibility and elastic properties, together with its superior carrier mobility, transparency and inexpensive feature make graphene outstanding electrode for next-generation flexible and foldable electronics. Successfully developed chemical vapor deposition (CVD) method for growing large-scale graphene film renders its appropriateness for practical applications and mass roll-to-roll manufacture. In addition, graphene provides a good interfacial and low contact resistance to organic materials. More importantly, combination of its flexibility and strong adhesive force to the substrate, i.e., Van der Waals (adhesive energy of 0.45 Jm⁻² on SiO₂), provides graphene an excellent electrode naturally adhered onto the elastic substrate for flexible and stretchable electronic applications.

However, traditional fabricating approaches, including well-established semiconducting techniques and organic solution processes, are first to deposit the graphene film on the selected rigid, flat, or smooth substrates, and then conduct the fabrication procedures on the conventional substrates following a bottom-up fabrication scheme. In those approaches, the substrate is pre-determined and restricted by the processing conditions, chemical solvent compatibility, and handling requirements. Such restrictions lead to the difficulty in fabricating devices on arbitrary non-conventional substrates for more advanced applications. Alternatively, a promising strategy is to carry out the well-established fabrication processes on a conventional planar substrate and then transfer the as-prepared devices onto the desired substrates such as soft plastic, non-planar substrates, functional devices or integrated circuits for avoiding unsuitable fabricating processes. However, to date, those fabrication processes are still complicated and there remains a need and further development for the graphene film.

### SUMMARY OF THE INVENTION

One aspect of the present invention is to provide a flexible and stretchable graphene film, comprising a graphene layer and a functional layer formed on the graphene layer.

Preferably, the functional layer contains an insulating polymer and a conductive material. Preferably, the insulating polymer is at least one selected from of the group consisting of poly(methyl methacrylate), polyimide, polyacrylate, polyurethane, polyethylene terephthalate, polyethersulfone, polyether ether ketone, polycarbonate, poly(dimethylsiloxane), and a combination thereof. Preferably, the insulating polymer has a concentration in the range of 7 to 200 mg/ml.

Preferably, the conductive material is at least one selected from the group consisting of polyaniline, polythiophene, polyethylenedioxythiopene (PEDOT), polyimide, polystyrenesulfonate (PSS), polypyrrole, polyacetylene, poly(p-phenylene), poly(p-phenylene sulfide), poly(p-phenylene vinylene), polythiophene poly(thienylene vinylene), carbon nanotube, metal nanoparticles, and a combination thereof.

Preferably, the functional layer has a thickness of 1 to 400 nm.

Preferably, the flexible and stretchable graphene film is further transferred onto a substrate. Preferably, the substrate is an unconventional substrate.

Preferably, the flexible and stretchable graphene film further has a metal layer deposited on the functional layer, and exhibits a characteristic of a write-once-read-many-times (WORM) type memory or a re-writable type memory.

Another aspect of the present invention is to provide a method of producing a graphene film, comprising: (a) providing a carrier, and a graphene layer is formed on the surface of the carrier; (b) forming a functional layer containing an insulating polymer and a conductive material on a top portion of the graphene film; and (c) removing the carrier. Preferably, the method further comprises the following steps: (d) transferring the graphene film onto a pre-strained substrate; and (e) releasing the pre-strained substrate. Preferably, the pre-strained substrate is an elastomer.

Preferably, the graphene layer is formed by chemical vapor deposition (CVD) method. Preferably, the functional layer is formed by bar-coating, wire bar-coating, spin coating, dip coating, casting, micro gravure coating, gravure coating, roll coating, immersion coating, spray coating, screen printing, flexo printing, offset printing, or inkjet printing method.

Still another aspect of the present invention is to provide an apparatus, which has the flexible and stretchable graphene film of the present invention.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 (a) Schematic diagram for the fabrication process of the memory label. (b) Measurement arrangement of the GMML.

FIG. 2 Electrical properties of the memory cell: (a), (d) I-V characteristics for the device on flat and bending conditions, respectively. The inset in (a) shows the ON/FOO ratio as a function of forward voltage while that in (d) presents a photograph of the GMML bent at R=10 mm. (b), (e) The programmed data retention ability at the reading voltage of +IV before and after bending, respectively. (c), (f) Effects of a succession of pulse reading bias of +IV on the written ON (OFF) state before and after bending. The inset shows the pulse used for the measurement.

FIG. 3 (a) Free-standing GMML after etching away the copper foil. (b)-(g) Photographs with the corresponding IV-curves alongside for the GMMLs transferred onto various non-conventional substrates, including on the outside surface of a cylindrical vial (b), a glove (PVC) (c), a medical wristband (d), a coin (e), a P-type silicon (f), and an organic diode (g). (The size of GMML is about 1 cm².) FIG. 4 Electrical properties of the RSOM: (a). (d) I-V characteristics for the memory device on flat and bending conditions, respectively. The inset in (d) presents the image of the RSOM bent at R=10 mm. (b), (e) The DC cyclic switching tests for the RSOM at the reading voltage of +0.5V on flat and curvy conditions, respectively. (c), (f) The programmed data retention ability at the reading voltage of +0.5V on flat and curvy conditions, respectively.

FIG. 5 Demonstrations of the RSOMs labeled onto various non-conventional substrates with the corresponding I-V curves alongside, including on (a) a business card, (b) a fake nail, (c) the outside surface of a cylindrical vial, (d) a medical wristband, (e) a peelable Post-it Flag, (f) a 3M scotch magic tape. (The area of RSOM is about 1 cm².)

FIG. 6 (a) Effect of the PMMA content on the OFF-state, ON-state current, and ON/OFF state current ratio of the Al/PMMA:P3HT/graphene devices. (b) Effect of the thickness of the polymer matrix on the turn-on voltage. (c) Cell area dependence of the ON- and OFF-state current.

FIG. 7 Fabrication process for the stretchable organic memory devices.

FIG. 8 (a) Top-view and (b) angle-view scanning electron microscopy images of the rippled graphene film.

FIG. 9 Electrical properties of the buckled organic memory: (a) I-V characteristics of the buckled memory device; (b) the ON/OFF ratio as a function of forward bias.

FIG. 10 Electrical properties of the organic memory under post-strain: (a) the programmed high-conductivity ON-state under different strain conditions; (b) the retention time test of the stretchable memory under different strain conditions.

FIG. 11 (a) to (e) Electrical switching behavior tests for the stretchable organic memory under different stretching conditions from 10% to 50%.

FIG. 12 The durability test for the coded state under repetitive stretching (30% strain) and relaxing (0% strain) cycles. (a) The stretchable organic memory under 30% strain. (b) The coded ON-state under repetitive stretching (30% strain) and relaxing (0% strain) for 500 cycles. (c) The initial OFF-state under

### DETAILED DESCRIPTION OF THE PREFERRED EMBODIMENTS

Hereinafter, illustrative embodiments and examples of the present disclosure will be described in detail with reference to the accompanying drawings so that inventive concept may be readily implemented by those skilled in the art.

However, it is to be noted that the present disclosure is not limited to the illustrative embodiments but can be realized in various other ways. In the drawings, certain parts not directly relevant to the description are omitted to enhance the clarity of the drawings, and like reference numerals denote like parts throughout the whole document.

Throughout the whole document, the term “comprises or includes” and/or “comprising or including” used in the document means that one or more other components, steps, operations, and/or the existence or addition of elements are not excluded in addition to the described components, steps, operations and/or elements. The terms “about or approximately” or “substantially” are intended to have meanings close to numerical values or ranges specified with an allowable error and intended to prevent accurate or absolute numerical values disclosed for understanding of the present invention from being illegally or unfairly used by any unconscionable third party.

[Flexible and Stretchable Graphene Film and Apparatus Containing the Same]

The present invention is to provide a flexible and stretchable graphene film, comprising a graphene layer and a functional layer formed on the graphene layer. The term “functional layer” used herein refers to a layer functioned as a protective layer as well as an active layer. The protective layer acts as a support for the graphene layer and is used to minimize the damage to CVD-derived graphene during the stripping process from the metal carrier. The active layer gives the graphene film to have different properties so that the graphene film can be further used in wide variety applications such as data storage applications, transistors, light-emitting diodes, sensors and power supplies. In an illustrative embodiment, the functional layer contains an insulating polymer and a conductive material.

The insulating polymer is at least one selected from of the group consisting of poly(methyl methacrylate) (PMMA), polyimide, polyacrylate, polyurethane, polyethylene terephthalate, polyethersulfone, polyether ether ketone, polycarbonate, poly(dimethylsiloxane), and a combination thereof. Preferably, the insulating polymer is PMMA. The insulating polymer has a concentration in the range of 5 to 200 mg/ml, preferably 7 to 36 mg/ml for giving the graphene film of the present invention a characteristics of rewritable memory. However, to give the graphene film the characteristics of write-once-read-many-times (WORM) type memory, the insulating polymer shall has a concentration over 7 mg/ml.

The conductive material is at least one selected from the group consisting of polyaniline, polythiophene, polyethylenedioxythiopene (PEDOT), polyimide, polystyrenesulfonate (PSS), polypyrrole, polyacetylene, poly(p-phenylene), poly(p-phenylene sulfide), poly(p-phenylene vinylene), polythiophene poly(thienylene vinylene), carbon nanotube, metal nanoparticles, and a combination thereof. Selection of the conductive material is based on the application of the graphene film of the present invention. For example, if the graphene film is for organic memory application, then semiconducting macromolecular polymer may be selected as a conductive material; if the graphene film is for transistors or sensors, then carbon nanotube, metal nanoparticles may be selected, etc. With respect to the terms “conductive polymer” and “conductive inorganic material” throughout the whole document, the term “conductive” is construed to include both conductivity as a conductor and conductivity as a semiconductor. The concentration of the conductive material is not limited, preferably, higher than that of the insulating polymer.

In another illustrative embodiment, the functional layer may be a thin film having thickness of about 1 nm to 400 nm, preferably about 10 nm to 150 nm, and most preferably about 50 nm to 100 nm. However, the present disclosure is not limited thereto and persons having ordinary skill in the art can adjust the thickness to comply with their need.

The flexible and stretchable graphene film of the present invention is further transferred onto a substrate. The term “unconventional substrate” refers to any substrate such as a conductive substrate, an insulating substrate, a transparent substrate, a flexible substrate, or a transparent and flexible substrate. However, the present disclosure is not limited thereto. In the present invention, the graphene layer in the graphene film is used as an adhesive layer to be attached to the substrate.

According to the graphene film of the present invention, the graphene film can be applied to various apparatus. Thus, the present invention further provides an apparatus comprising the graphene film of the present invention, such as transferable transistors, light-emitting diodes, sensors and power supplies. For example, the present invention provides a graphene transparent electrode, including the above-described graphene film. An electrode including the graphene film may be applied to various fields such as a liquid crystal display device, an electronic paper display device, an organic light emitting display device, a tough screen, a flexible display apparatus, an organic LED, a solar cell, and the like.

Compared to conventional graphene film, the stretchable, transferable and flexible graphene film of the present invention offers numerous advantages. Firstly, the graphene film can be easily transferred onto desired substrates; hence harsh synthesis and unaccustomed fabrication steps on non-conventional substrates can be avoided. Secondly, the transferability onto organic devices of the graphene film can minimize the possible solvent damage issue suffered from traditional solution-phase techniques. This unique transfer feature could advance the development of 3D-stacked memories or multiple organic electronics modules. Thirdly, there is a freedom to transfer entire graphene film on substrates of various types, including rigid, flexible, stretchable, non-planar, rough, etc. The versatile substrate selection advantage could greatly broaden memory applications in advanced electronics such as flexible, wearable or epidermal electronics. Considering the cost-effective production, the graphene film of the present invention is simple and high-yield; moreover, the integration of the flexible graphene bottom electrode and the polymer memory composite is suitable for roll-to-roll industrial manufacturing.

[Method for Preparing the Flexible and Stretchable Graphene Film]

The present invention provides a method of producing a graphene film, comprising: (a) providing a carrier, and a graphene layer is formed on the surface of the carrier, (b) forming a functional layer containing an insulating polymer and a conductive material on a top portion of the graphene film; and (c) dissolving the carrier by an etchant.

As the method for forming the graphene film, any method generally used in the art of the present disclosure to grow graphene may be used without limitation. For example, a chemical vapor deposition (CVD) method may be used. However, the present disclosure is not limited thereto. The chemical vapor deposition method may include rapid thermal chemical vapour deposition (RTCVD), inductively coupled plasma-chemical vapor deposition (ICP-CVD), low pressure chemical vapor deposition (LPCVD), atmospheric pressure chemical vapor deposition (APCVD), metal organic chemical vapor deposition (MOCVD), and plasma-enhanced chemical vapor deposition (PECVD). However, the present disclosure is not limited thereto.

In another illustrative embodiment, the graphene film may be formed on a metal catalyst thin film (or carrier) through a chemical vapor deposition method. For example, the metal catalyst thin film may include one selected from the group consisting of Ni, Cu, Co, Fe, Pt, Au, Al, Cr, Mg, Mn, Mo, Rh, Si, Ta, Ti, W, U, V, Zr, Ge, Ru, Ir, brass, bronze, nickel, stainless steel, and a combination thereof.

For the preparation of the graphene film, graphene can be grown by injecting a vapor carbon supply source to carrier, and heating the carrier. In an illustrative embodiment, the carrier is placed in a chamber. While vaporously injecting, into the chamber, a carbon supply source such as carbon monoxide, methane, ethane, ethylene, ethanol, acetylene, propane, butane, butadiene, pentane, pentene, cyclopentadiene, hexane, cyclohexane, benzene, or toluene into the chamber, the substrate is heated, for example, at a temperature of about 300° C. to about 2,000° C. As a result, graphene is generated while carbon components existing in the carbon supply source are bonded to one another to form a hexagonal plate shape structure. By cooling the graphene, the graphene film in a uniformed arrangement state is obtained. However, the method for forming graphene on the carrier is not limited to the chemical vapor deposition method. In an illustrative embodiment of the present disclosure, any method that forms graphene on the carrier may be used. It is understood that the present disclosure is not limited to the certain method that forms graphene on the carrier.

The functional layer is then formed on the graphene film by various methods, such as bar-coating, wire bar-coating, spin coating, dip coating, casting, micro gravure coating, gravure coating, roll coating, immersion coating, spray coating, screen printing, flexo printing, offset printing, or inkjet printing method. However, the present disclosure is not limited thereto.

Dissolving or removing the carrier may be performed through dry etching using an etching apparatus such as reactive ion etching (RIE), inductively coupled plasma RIE (ICP-RIE), electron cyclotron resonance RIE (ECR-RIE), reactive ion beam etching (RIBE), or chemical assistant ion beam etching (CAIBE); wet etching using an etchant such as potassium hydroxide (KOH), tetra methyl ammonium hydroxide (TMAH), ethylene diamine pyrocatechol (EDP), burrered oxide etch (BOE), FeCl₃, Fe(NO3)₃, HF, H₂SO₄, HNO₃, HPO₄, HCl, NaF, KF, NH₄F, AlF₃, NaHF₂, KHF₂, NH₄HF₂, HBF₄, and NH₄BF₄; or a chemical mechanical polishing process using an oxide film etching agent.

According to another illustrative embodiment, the graphene film is further transferred onto a substrate. For example, the substrate 110 may be a substrate formed of the following material: polyethylene terephthalate (PET), polybuthylene terephthalate (PBT), polysilane, polysiloxane, polysilazane, polyethylene (PE), polycarbosilane, polyacrylate, polymethacrylate, polymethylacrylate, PMMA, polyethylacrylate, cyclic olefin copolymer (COC), polyethylmetacrylate, cyclic olefin polymer COP, polypropylene (PP), polyimide (PI), polystyrene (PS), polyvinylchloride (PVC), polyacetal (POM), polyetheretherketone (PEEK), polyestersulfon (PES), polytetrafluoroethylene (PTFE), or polyvinylidenefloride (PVDF), perfluoroalkyl polymer (PFA). However, the present disclosure is not limited thereto. Preferably, the graphene film is transferred onto a pre-strained substrate, and then releasing the pre-strained substrate. Thus, the obtained graphene film is buckled and can be elongated by conversion of the vertical displacement and planar strain, which realizes the stretchability. In a preferable embodiment, the pre-strained substrate is an elastomer, such as unsaturated rubbers, saturated rubbers or other types of elastomer, such as theromoplastic elastomer, elastin, polysulfide rubber, and the like.

Compared to traditional method, where the protective layer is first spin-coated or inject printed onto the graphene film to act as a support, an etchant is then used to remove the metal catalyst (carrier), after which the protective layer/graphene stack is transferred to another substrate, and finally solvents are then used to remove the protective layer to complete the graphene film transfer, the present invention omits the step of removing the functional layer, which serves a protective layer as well as a conductive layer.

According to the present invention, the graphene film is ready to be transferred onto desired substrates with a simple one-step transfer process, which will be largely beneficial to a range of advanced electronic applications such as flexible, wearable computers, and epidermal electronics. In addition, unlike the conventional protective layer on graphene film shall be removed, the graphene film of the present invention can be simply transferred without removing the functional layer, thus paves a promising way for vertical stacking organic electronics and creating flexible 3D circuitries.

### Example

Hereinafter, the present disclosure will be specifically described with reference to examples and drawings. However, the present disclosure is not limited to the examples and the drawings.

### Example 1

### Synthesis of Graphene Film with Further Fabrication as a Transferable and Flexible Sticker-Type Memory Label Named “Graphene Macromolecular Memory Lable (GMML)”

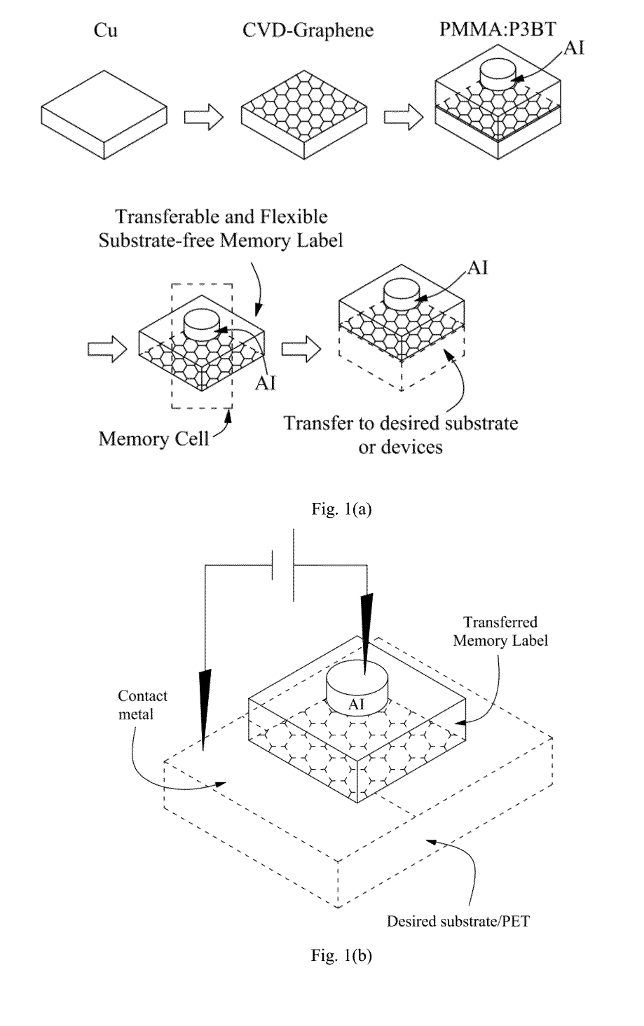

FIG. 1a shows a schematic fabrication process of Example 1. A graphene layer was grown on copper foil (carrier) using CVD technique. Detailed synthesis of the CVD-derived graphene layer can be found in prior art and is not described herein. A polymer solution composed of poly(3-butylthiophene) (10 mg, Sigma-Aldrich), chlorobenzene (0.5 mL), and poly(methyl methacrylate) (0.5 mL, 950 k A4, Micro-Chem) was stirred at 50° C. for 1 day. The resulting solution was dropped on the graphene layer for 10 min before starting the spin coating process at a rate of 2500 rpm for 20 sec (˜120 nm by alpha step) to form a functional layer. To complete the device fabrication, an aluminum layer (300 nm) was thermally deposited on top of the functional layer at a pressure of 2×10⁻⁶ torr. The Al electrodes were circular patterns with a diameter of 0.54 mm and the typical active area defined by the overlapping of graphene and Al electrodes was 0.23 mm². Finally, the sacrificial Cu foil was removed by immersing the device into an aqueous solution of iron nitrate (Fe(NO₃)₃) (0.05 g/mL) for ˜4 hours. Then, this graphene layer/PMMA:P3BT (functional layer)/Al memory label (GMML) was transferred to DI water to wash away the Cu etchant to obtain the graphene film of the present invention.

### Experimental Example 1

In order to perform I-V measurement, the graphene film was transferred to the polyethylene terephthalate (PET) substrate and dried naturally, and a contact metal (Ni) was pre-deposited on the border of the PET and partially contacted with the graphene film, as shown in FIG. 1(b). In this configuration, graphene layer serves as the flexible bottom electrode and the adhesion face for transferring the GMML on desired substrates.

The electrical characterizations of the GMML were measured by an Agilent 4156C semiconductor parameter analyzer equipped with an Agilent 41501B. All electrical properties were characterized at room temperature and ambient conditions, unless otherwise stated.

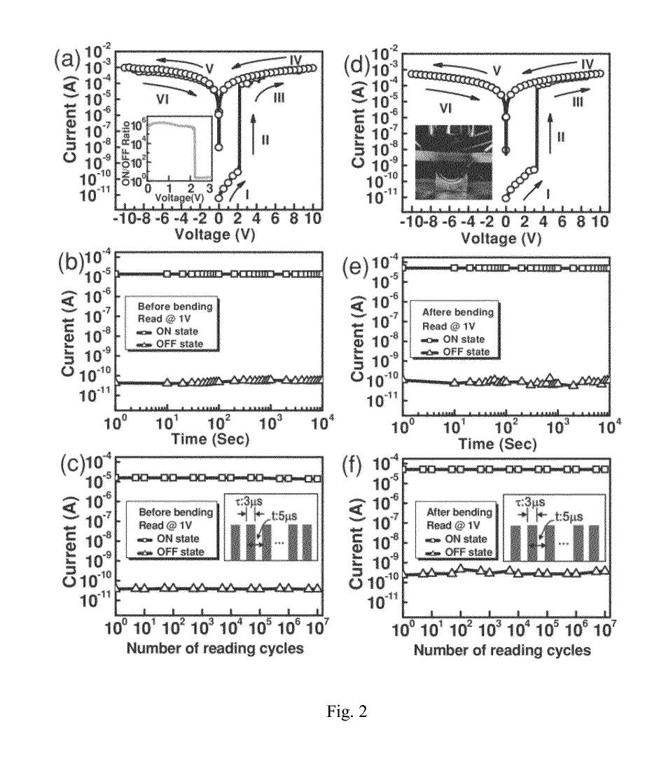

We evaluated the electrical switching and memory effects of the GMML both on flat and under bending conditions. FIG. 2a shows the memory characteristics of the GMML on flat condition. The arrows denote the voltage sweeping direction. Initially, as the bias swept from 0 to +2.2 V, the as-fabricated device was in a low-conductivity state (OFF-state, stage I) with the currents in a quite low level of 10⁻¹¹ to 10⁻¹⁰ A. Once the applied voltage exceeded a turn-on voltage of +2.2 V, a rapid increase in the current flow was observed (stage II), indicating a switch from the low- (OFF) to the high-conductivity (ON) state with a high ON/OFF current ratio of ˜10⁶ (inset in FIG. 2a). The transition from the OFF- to ON-state is equivalent to the “writing” command in digital storage devices and the high ON/OFF current ratio promises a low misreading probability in data access. Compared to other different types of graphene-based memory devices, the GMML reveals a relatively lower writing voltage, suggesting a promising application for low power consumed memory. The programmed device retained this high-conductivity state in the following scans (stages III and IV). Additionally, this high-conductivity state remained even when the power was off, indicating a nonvolatile feature of the memory effect. The high-conductivity state is not retrievable by applying the reverse bias scans (stages V and VI), indicating that the GMML exhibits a characteristic of write-once-read-many-times (WORM)-type memory.

Besides the low writing voltage and low misreading probability, the device stability, including data retention and stimulus effect of continuous pulse reading stress, is also an important character in practical WORM-type memory applications. For testing the data retention ability, the ON/OFF state was probed at regular intervals using the reading voltage of +1 V. As shown in FIG. 2(b), the OFF and programmed ON state were remained in the same order of magnitude without significant degradations after considerable duration for 10⁴ sec. This excellent electrical stability without applying a constant stress bias indicates good applications in nonvolatile memory. For exploring the effect of the pulse reading stress, the device was initially started from the OFF- (or ON-) state and continuously read out under a successive pulse reading biases of +1 V with a pulse duration of 3 μs and a period of 5 μs. As shown in FIG. 2(c), the coded information was fairly stable even under 10⁷ continuous reading pulses. From the application perspective, the stable performance of the GMML provided a promising commercial potential for a broad variety of memory applications, for example portable disks, low-cost electrical labels, and radio-frequency identification (RFID) tags.

### Experimental Example 2

The GMML was further characterized under bending condition and the results were compared with that of the flat case. The GMML was bent into a concave with bending radius of 10 mm (inset in FIG. 2(d)). The procedure for the electrical measurement is identical to that of the flat condition. As depicted in FIG. 2(d), the bent GMML revealed the similar WORM-type memory behavior with the similar current level as that of the flat condition. These memory features were reproducible and stable after repetitive bending. FIG. 2(e) shows the associated data retention ability of the GMML under bending condition. Similarly, the programmed state can be manifestly distinguished with a high ON/OFF current ratio of ˜10⁶ and can sustain over 10⁴ s without any degradation. And, the coded information can be correctly accessed even after reading more than 10⁷ times (FIG. 2(f)). Clearly, the excellent data retention and stability properties of the GMML were not swayed by the bent situation, indicating that the performance of the GMML is reliable regardless of its physical presentation.

### Experimental Example 3

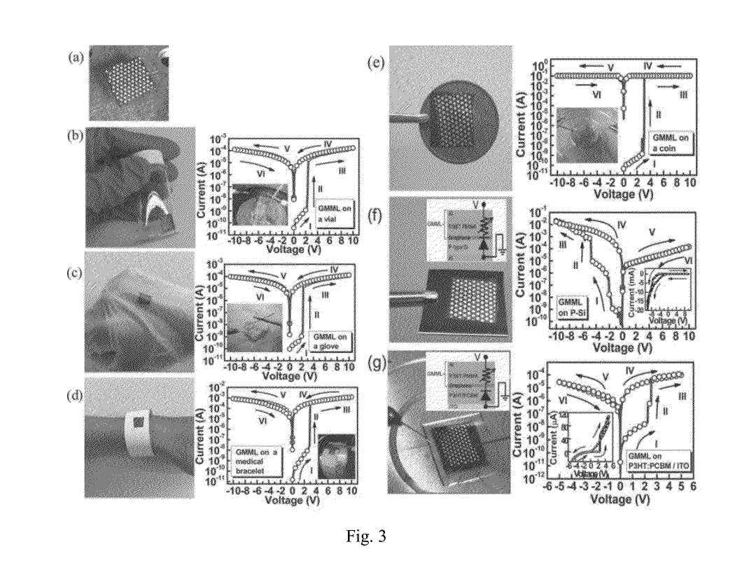

After confirming the excellent performances of the GMML on the PET substrate with various geometric deformation, the GMML was further transferred onto various challenging non-conventional substrates. FIG. 3(a) shows the free-standing GMML after removing the supporting copper foil. This free-standing GMML is ready to be transferred onto diverse substrates, both rigid and soft ones. Identical fabrication and measurement procedures were used for these transferred devices as mentioned on PET substrate. The corresponding I-V characteristics were presented alongside the photos of the transferred GMML. First, the GMML was transferred onto a rigid cylindrical vial (with a diameter of 20 mm) (FIG. 3(b)), indicating that the GMML can be easily transferred onto non-planar surfaces and exhibits similar memory behaviors. Next, the GMML was transferred onto a wearable and stretchable PVC glove, as shown in FIG. 3(c), and the memory cells still performed normally, which provides a successful example for developing wearable electronics. The GMML also works on a bent medical wristband (FIG. 3(d)), suggesting a real world flexible electronic applications. Also, a rougher and conductive coin surface for memory behavior test was performed (FIG. 3(e)) and the result shows that the ON-state current is higher than other substrates, which might be attributed to the full coverage of the graphene film by the conductive copper surface of the coin resulting in lower in-plane resistance. Subsequently, the GMML was transferred onto a P-type Si wafer to form a 1D-1R configuration (FIG. 3(f)). At a read voltage of ±1V, the ON-state currents in the forward and reverse biases are ˜10⁻⁴ and ˜10⁻⁶ A, respectively, achieving a rectification ratio of approximately two orders of magnitude for the hybrid memory device in the ON-state. Finally, an organic-based tandem diode-memory device (FIG. 3g) was used. The rectifying characteristics of this tandem device come from the bottom organic diode with a rectification ratio of about one order of magnitude at a read voltage of ±0.1 V.

From the above demonstrations, it is proved that GMML can be easily transferred onto diverse unconventional substrates, including soft, flexed ones or functional organic/inorganic devices with 100% fidelity.

### Example 2

### Synthesis of Graphene Film with Further Fabrication as a Transferable, Rewritable and Flexible Sticker-Type Memory Label Named “Re-Writable Sticker-Type Organic Memory (RSOM)”

The fabrication process was similar to Example 1. A graphene layer was grown on copper foil (carrier) using CVD technique. A polymer blending solution was prepared by mixing poly(methyl methacrylate) (PMMA, 18 mg, M_{w}=950 k, Sigma Aldrich Co.) and poly(3-hexylthiophene) (P3HT, 2 mg, M_{w}=40 k, Luminescence Technology Co.) in chlorobenzene (CB, 1 mL) with stirring at 50° C. for one day. Afterward, the as-prepared solution was spin-coated onto the graphene-grown copper foil at a rate of 2000 rpm for 20 sec (˜130 nm by alpha step) followed by drying under reduced pressure to form a functional layer. Subsequently, the underlay copper foil was dissolved by a Cu etchant, an aqueous solution of iron nitrate (Fe(NO₃)₃) (0.05 g/mL). Next, the sticker-type organic memory (ROSM) was firstly transferred to deionized water for washing away the Cu etchant to obtain the graphene film of the present invention. All of the electrical characterizations of the fabricated memory device were measured by a Keithley 4200 semiconductor parameter analyzer. All electrical properties were characterized at room temperature and ambient conditions.

### Experimental Example 1

In order to perform I-V measurement, the graphene film was transferred to the polyethylene terephthalate (PET) substrate and dried naturally. The top electrodes of the device, 300-nm-thick aluminum, were thermally deposited onto the top of sticker-type organic memory at a pressure of 2×10′⁶ torr through a shadow mask with circular patterns. The area of memory cell defined by the sandwich of the top Al electrode and graphene sheet was 0.23 mm². In order to probe the bottom graphene electrode (graphene layer), a contact metal (Ni) for the graphene was pre-deposited on the margin of the PET substrate and partially connected with the bottom graphene electrode. The electrical switching behavior and bistable memory effect of the sticker-type memory (graphene layer/PMMA:P3HT (functional layer)/Al) are illustrated by the current-voltage (I-V) characteristics, as shown in FIG. 4(a). In the beginning, we measured the sticker-type organic memory on the PET under flat condition. The bias was applied onto the top Al electrode with an appropriate current compliance of 0.0001 A to prevent the device from hard breakdown, and the graphene electrode was grounded. The arrows point out the sweeping direction of the applied voltage. Initially, as the bias sweeping from 0 to 6 V, the current starts in a low-conductivity (OFF) state within a quit low current level of ˜10⁻¹⁰ A and increases monotonically in the low bias regime. As the applied bias is greater than the turn-on voltage (about +3.6 V), a sudden increase in the current flow from the low- (OFF) to the high-conductivity (ON) state is observed. This electrical switching behavior corresponds to the “writing” process in the digital storage device. The programmed high-current state can be maintained during the sequential forward sweeping, indicating the nonvolatile feature of the memory. Typical values of the ON- and OFF-state currents at the reading voltage of 0.5 V are 10⁻⁵ A and 10⁻¹⁰ A, respectively, with a high ON/OFF ratio of ˜10⁵, making a ready recognition for the digital information (“0” or “1”) programmed in the sticker-type memory. Afterward, as the bias is negatively swept with no current compliance, the programmed high-current state can be retrieved to the original low-conductivity (OFF) state at a suitable negative bias (about −2.6 V), indicating a rewritable feature of the memory effect. This reinstated process is equivalent to the “erasing” process in the digital memory applications. The erased OFF state can be reprogrammed to the ON state again in the subsequent writing bias sweep. Thus, the I-V characteristic of the sticker-type memory exhibits a typical rewritable switching memory behavior.

In order to investigate the re-writability of the erasable sticker-type memory, such writing and erasing processes were cyclically switched by dc sweeping mode, and the current was read out at the reading voltage of 0.5 V in each cyclic sweep. As shown in FIG. 4(b), the device can be operated successfully more than 80 times, and still exhibits a large ON/OFF current ratio of about 10⁵. In addition, to assess the data retention ability of the memory, the OFF and programmed ON states were read out at the 0.5 V after regular intervals, respectively. FIG. 4(c) shows the results that the OFF-state and coded ON-state currents were retainable in the programmed state with the same order for over 1.5 hours. According to the above results, the sticker-type memory exhibits a reversible and steady bistable electrical memory behavior, promoting them widely used in commercial electronic systems, such as portable disks, smart pads, digital players and cameras, for nonvolatile information storage.

### Experimental Example 2

For further evaluating the feasibility of the RSOM for flexible memory applications, the bistable switching behavior of the RSOM was examined after bending. As shown in the insert of FIG. 4(d), the memory sticker on PET was bent into a concave with surface curvature radius of 10 mm. The measurement condition was identical to the flat one. As represented in FIG. 4(d), the bended RSOM exhibits the resembling electrical hysteresis behaviors, indicative of its capability for digital information storage under different geometric conditions. The ON/OFF current ratio at the reading bias of 0.5 V under bending is about 10⁵ which is as large as its flat status, meaning that the manifest memory window is not swayed by the curvy situation. The associated cycling tests and retention ability were also employed to confirm its re-writability and memory performance after rolling deformation. FIG. 4(e) shows that its re-writable capability and ON/OFF switching behaviors can work well even after 80 times of dc sweeping, indicative of the reproducibility for flexible memory applications. Moreover, the ON/OFF current ratio can be manifestly recognized more than 1.5 hours, indicative of its retention ability is not affected after bending. Accordingly, the RSOM can maintain the excellent digital storage functions irrespective of its physical bending conditions, promising its application potential for data storage in flexible electronics and various surfaces.

### Experimental Example 3

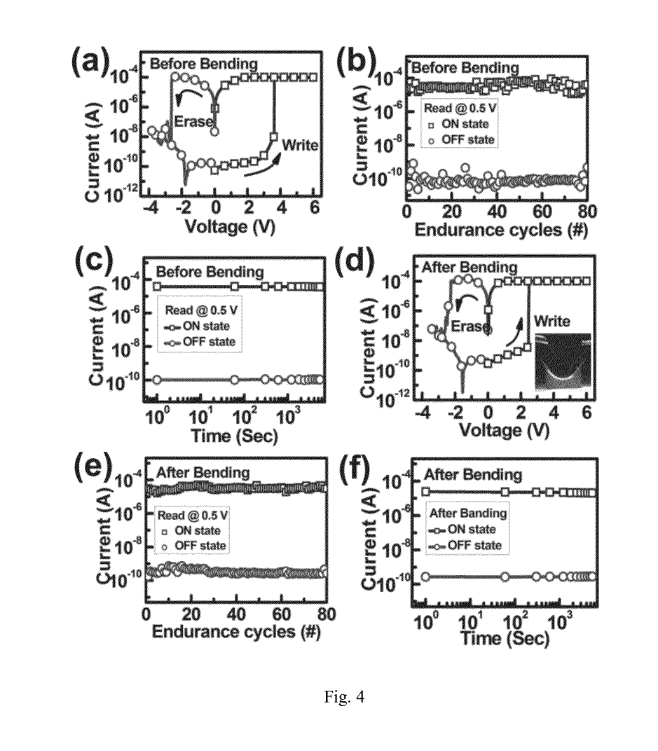

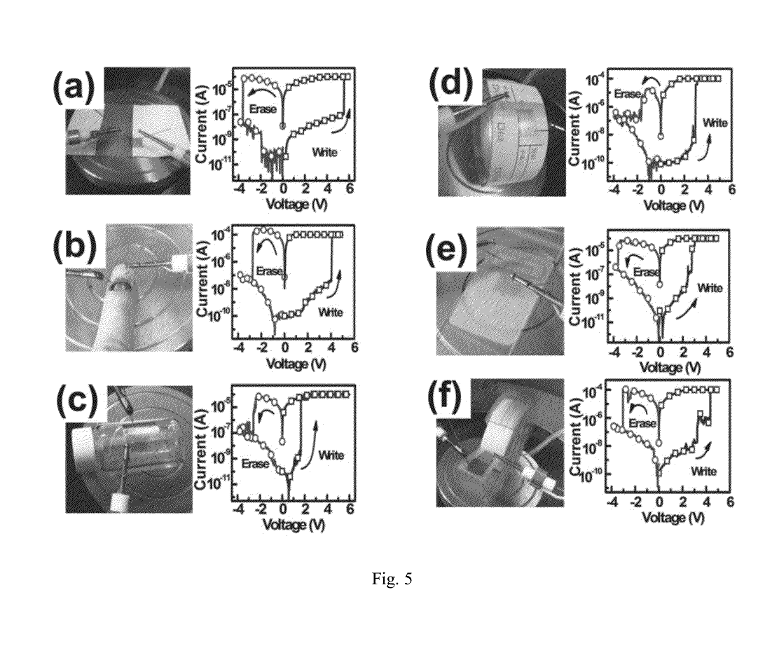

Subsequently, in order to broaden the technical application of the electrically erasable sticker-type memory, we transferred it onto various nonconventional substrates and test its electrical switching behaviors. The corresponding electrical measurements are presented alongside the photos of the RSOM on diverse substrates. Firstly, as shown in FIG. 5(a), the sticker-type memory can be easily transferred on a business card and manipulated unerringly. We have also tried to label the sticker-type memories onto various non-planar surfaces such as fake nail (FIG. 5(b)) and rigid cylindrical vial (with a diameter of 20 mm) (FIG. 5(c)) and measured their memory behaviors. The results show that the sticker-type memory can function normally regardless of its physical presentation. FIG. 5(d) demonstrates the memory sticker operated on a bent medical wristband, illustrating its promising application in future flexible electronics for information storage. Next, the sticker-type memories were successfully placed onto a peelable 3M Post-it Tabs and 3M Scotch magic tape as depicted in FIGS. 5(e) and (f), respectively, and both of the stuck memories exhibit regular bistable memory features. The peelable tapes enable the re-writable organic memory sticker removal and re-use on different substrates. As a result, the proposed RSOM based on the mechanically flexible and elastic graphene electrode and organic material can greatly expand the digital information storage applications on desired non-conventional substrates. Moreover, the fabricating processes shown here are very simple, low-temperature, and the sticker feature of the re-writable organic memory with no chemically washing away for the protective layer from graphene electrode may be also beneficial for the development of relevant areas, such as bendable, wearable and epidermal electronics. In addition, based on the roll-to-roll fabrication capability for CVD-graphene, the presented memory sticker might be industry-friendly for large-scale manufacture.

### Experimental Example 4

To further confirm the conductivity switching behaviors of the rewritable RSOM, we then measured the impacts of PMMA concentrations (FIG. 6(a)), the effect of film thickness of the polymer matrix (FIG. 6(b)), and the area dependence experiments (FIG. 6(c)). The effect of PMMA content in the polymer matrix for conductivity switching behaviors, including ON-current, OFF-current, and ON/OFF ratio, is summarized in FIG. 6(a). As shown in FIG. 6(a), the devices made from solution containing higher than 36 mg/ml PMMA are of a quite low current level of 10⁻¹²-10⁻¹¹ A both in OFF- and ON-states with ON/OFF current ratio less than 5, which indicates that the electrical switching behavior of the RSOM is greatly hindered by a more strengthened PMMA matrix in the active layer. This PMMA concentration dependence of the electrical switching behavior is consistent with our proposed mechanism that as increasing the concentration of PMMA, the metal particles may be blocked by the reinforced PMMA matrix, which accordingly stops the bipolar conductivity switching effect. Furthermore, the effect of film thickness of the polymer matrix is summarized in FIG. 6(b). As shown in FIG. 6(b), the turn-on voltage is proportional to the thickness of polymer matrix, which results from a longer distance for metal particles migration. Another indirect evidence can be also obtained by the fact that the ON-state current level is insensitive to the top Al electrode area. As shown in FIG. 6(c), the ON-state of the devices reveals in a similar current level with respect to different electrode areas. This can be understood that the current flow arises from a localized high conductivity metallic path, which connects the top Al electrode to the bottom graphene film. Hence, the ON-state current flow weakly depends on the electrode area.

### Example 3

### Synthesis of Stretchable Graphene Film with Further Fabrication as a Transferable and Stretchable Sticker-Type Memory Label

Substrate Preparation: Starting at the preparation of the poly(dimethylsiloxane) (PDMS) substrate, a curing agent and PDMS prepolymer (Dow Corning Sylgard 184) were mixed in a 1:20 weight ratio. The mixture was degassed by reducing pressure for 1 hour to avoid any air bubble in the mixture, and then poured onto the polished side of a silicon wafer. After curing, the PDMS membranes were produced with a thickness of ˜2 mm. Following peeling off the PDMS membranes, the PDMS substrate was cut out into a rectangle with an area of 2 cm×6 cm. Subsequently, the elastic PDMS substrate was clipped one side onto a glass slide and stretched along the length to ˜50% pre-strain, and then clipped the other side with slight component force toward orthogonal direction.

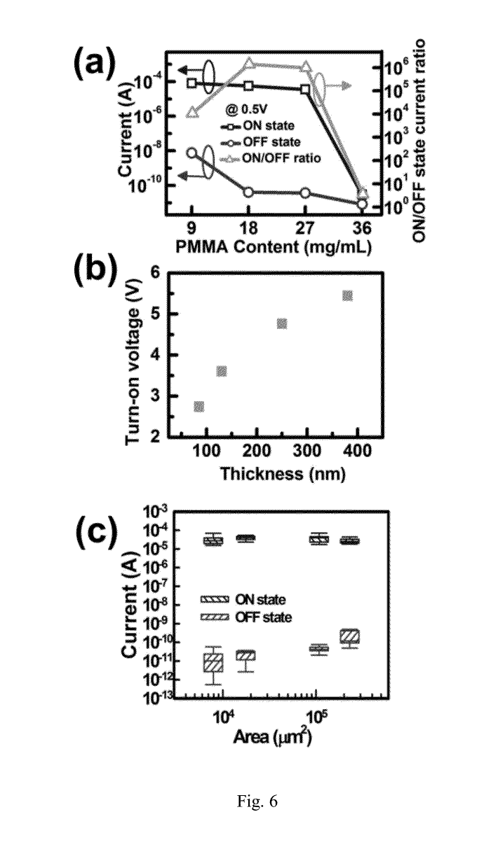

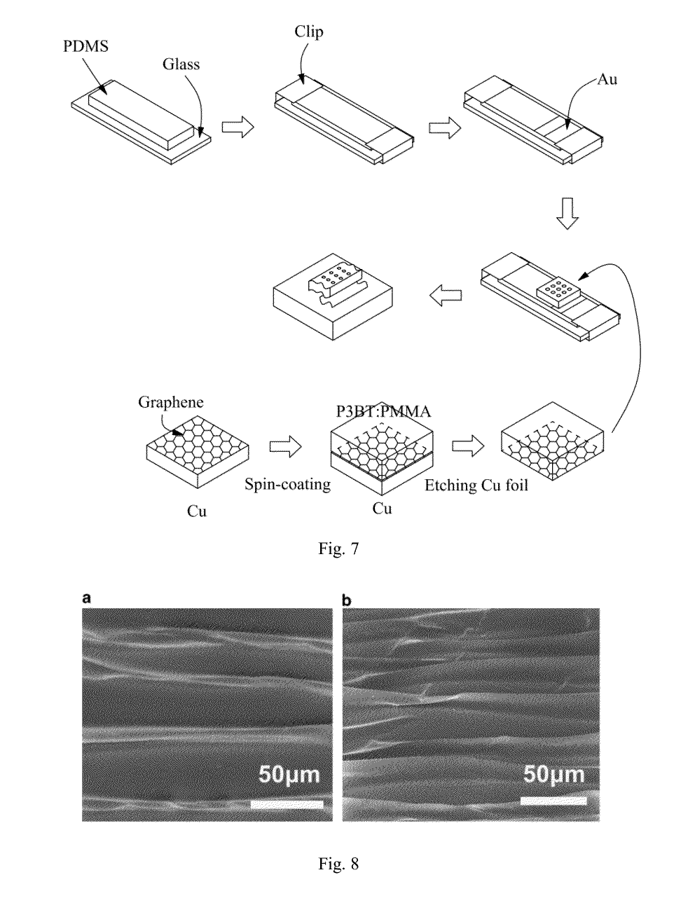

FIG. 7 presents the schematic processes of the stretchable organic memory. First, the graphene was grown by typical CVD method. Next, for the preparation of the organic memory of poly(methyl methacrylate): poly(3-butylthiophene) with a graphene bottom electrode, poly(3-butylthiophene) (10 mg, Sigma-Aldrich) was firstly dissolved in chlorobenzene (0.5 mL) and then blended with poly(methyl methacrylate) (0.5 mL, 950 k A4, Micro-Chem) with stirring at 50° C. for 1 day. After that, the prepared solution was dropped on an as-prepared CVD-graphene/copper foil for 10 min and then started the spin-coating process at a rate of 2500 rpm for 20 sec to form a functional layer, which acted as the active layer for the organic memory and also played as the protective layer for transferring graphene electrode. After drying under reducing pressure, the polymer-coated CVD-graphene/Cu foil was immersed to a copper etchant, e.g., an aqueous solution of iron nitrate (Fe(NO₃)₃) (0.05 g/mL) for ˜4 hours to etch the sacrificial copper foil. Then, the PMMA:P3BT/graphene film was firstly transferred to DI water to wash away the copper etchant and then transferred onto the pre-strained (by ˜50%) PDMS substrate clamped onto a glass slide. Here, strain is defined as (L−Lₒ)/Lₒ×100%, where L is the elongate length and L, is the original length. After drying naturally, 300 nm-aluminum electrodes were thermally deposited on the top of polymer layer with circular patterns. In order to probe the bottom graphene, a gold contact film was pre-deposited on the border of the PDMS and partially contacted with the bottom graphene electrode. Finally, after removing the clips carefully, the resulting devices spontaneously contracted and buckled on the released PDMS substrate.

The resulting film then spontaneously contracted and formed ripple on the released substrate. The fabrication here can be processed without any solvent and coating issue and post chemically washing away the protective layer for stripping graphene, which may be beneficial for the fabrication of devices on an elastic polymeric substrate and opens a way to vertically integrate with other stretchable organic devices. Also, combination of the organic memory and the protective layer of graphene may effectively reduce the fabricating processes and advantage for roll-to-roll industrial fabrication.

FIGS. 8(a) and 8(b) show the top-view and angled-view scanning electron microscopy images of the resulting rippled film. As shown in FIG. 8, after releasing the pre-strained PDMS, the film exhibited numerous ripples perpendicular to the pre-stretched tensile direction. The resulting buckled organic memory with the graphene underlay can be elongated by the conversion of the vertical delaminated displacement and planar strain, which realizes the stretchability of the buckled memory. The electrical characterizations of the stretchable organic memory (graphene film) were measured by a Keithley 4200-SCS semiconductor parameter analyzer. All electrical properties were performed at room temperature and ambient conditions.

### Experimental Example 1

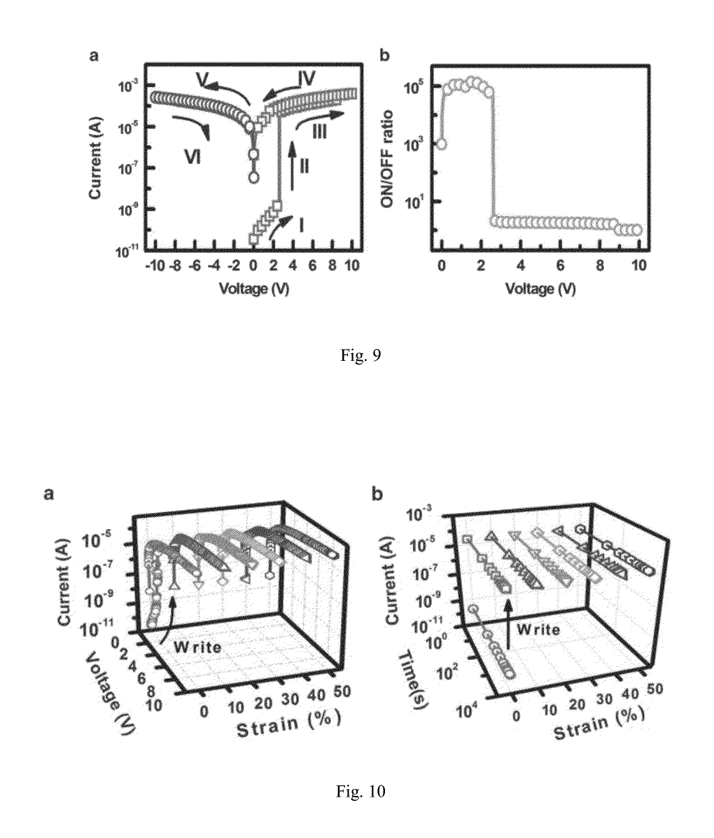

The electrical switching behaviors and memory effects of the wrinkled organic memory are illustrated by the current-voltage (I-V) measurement, as shown in FIG. 9(a). Initially, the current level of memory device remained low and increased gradually within the range of 10⁻¹¹˜10⁹ A during the low bias regime. When the bias was larger than the threshold voltage of approximately 2.6 V, the current level of the memory device sharply increased and switched to a high-current state from ˜10⁻⁹ to ˜10⁻⁴ A. This transition of the electrical characteristics from low-current (OFF, “0”) state to high-current (ON, “1”) state corresponds to the “writing” command in the digital memory device. As shown in FIG. 9(b), a high ON/OFF current ratio of ˜10⁵ at the reading voltage of 1 V renders the data stored in the buckled organic memory ready to be accessed with low misreading probability in access. Once the device switched to the ON-state, the programmed state was not retrievable during the following forward/negative sweep, indicating that the buckled organic memory exhibits a typical feature of write-once-read-many times (WORM)-type memory devices. The programmed ON-state remained in the high-current level even if the applied voltage was removed, indicative of the non-volatile feature of this memory behavior.

### Experimental Example 2

After characterizing the WORM-type organic memory under relaxed conditions, we then analyzed a programmed ON-state under different stretching conditions to confirm that the coded high-conductivity ON-state can be maintained after strain. As shown in FIG. 10 (a), the device in its ON-state can keep its programmed high-current status regardless of being re-strained from 10% to pre-strain, indicating that the memory effects were not affected by re-stretching the memory to pre-strain conditions, which is promising for its use with memory applications in stretchable electronic systems.

For memory devices, the data storage time is an important characteristic for practical, stretchable WORM-type memory applications. Thus, the ability to retain the coded digital data under various stretching conditions was tested. Coding of memory began with the OFF/ON-state at the original un-strained length and then the device's data retention ability was tested before the device was stretched. As shown in FIG. 10(b), the electrical WORM-type memory exhibited excellent retention ability for over 10⁴ s, and the high ON/OFF current ratio (˜10⁵) did not change after a considerable duration of time. After confirming the retention ability at the un-strained length, the data retention ability of the buckled organic memory was tested under various uniaxially elongating conditions by stretching from 10 to 50% strain. As seen in FIG. 10(b), the programmed low-conductivity ON-state demonstrated a strong retention ability (up to 10's), and no significant degradation was found when the device was re-stretched from 10 to 50% pre-strain. In additionally, the ON/OFF current ratio maintained its value in the same order of magnitude before the stretching of the device. These results suggest that the programmed digital signal can be accurately accessed for prolonged retention, even when re-stretching the device up to an initial pre-stretched value of 50% strain. The stability of the long-term retention might be expected because of the high activation energy of the P3BT-trapped charge carriers. At the writing voltage, numerous carriers were injected from the electrode, which filled up the P3BT trapping sites, and the percolation pathways of the carriers were formed among these charge-filled P3BTs, resulting in the electrical switching behavior and the subsequent high conductivity ON-state. Owing to the stability of the P3BT-trapped charges within the PMMA matrix, the organic memory can retain the programmed high conductivity state over the long term even after the power supply has been removed. The data stability of stretchable organic WORM-type memory can provide excellent digital information storage under various stretching conditions, which is also beneficial for the development of a wide variety of stretchable data storage applications, such as stretchable and portable disks, stretchable smart cards, biomedical skin markers and stretchable radio-frequency identification tags.

### Experimental Example 3

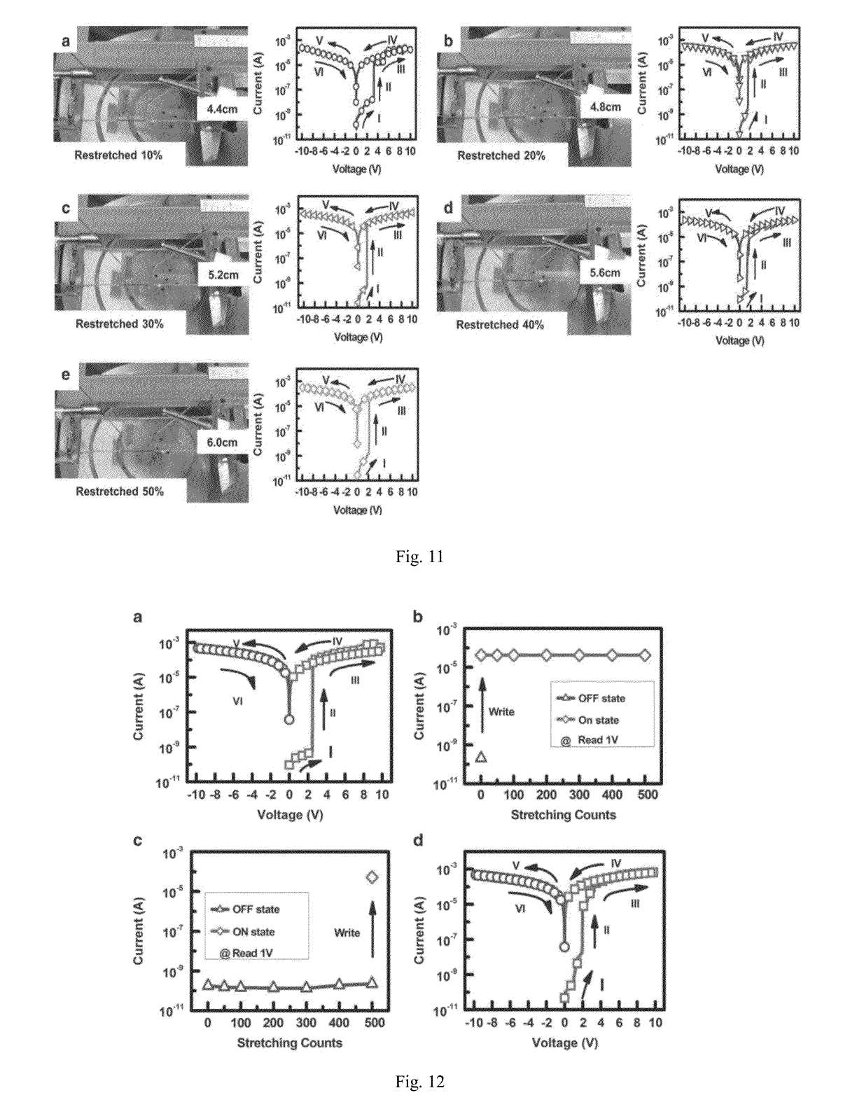

To evaluate the feasibility of using stretchable organic memory in stretchable electronic applications, the electrical switching behaviors from the different memory devices were tested under different stretching conditions. As shown in FIGS. 11 (a) to (e), the organic memory exhibited similar WORM-type memory switching behaviors under re-stretching from 10 to 50% strain. Under various strain conditions, a low-writing voltage (below 4 V) was retained, demonstrating the advantage of low-power consumption of stretchable memory applications. It is also worth mentioning that the distinguishable ON/OFF states at the reading voltage of 1 V were preserved under each stretching condition, holding the promise of a low probability of misreading data under different stretching conditions. These results suggest that WORM-type memory can operate well and be programmed well for digital data even if the organic memory is being elongated.

### Experimental Example 4

Next, the durability of the programmed ON/OFF state under stretching conditions was further investigated. In exploring the effect of cyclical stretching, the buckled WORM-type organic memory was initially programmed to the ON-state (FIG. 12(a)) and successively stretched to 30% and then released to its un-strained length.

As shown in FIG. 12(b), the coded ON state could preserve its programmed high-current conductivity and did not show obvious degradation after 500 cycles of being stretched by 30%, which is indicative of durability of the coded data even under numerous cycles of elongation and hence stretching. Identical testing was also conducted for the initial OFF-state. As shown in FIG. 12(c), the initial low-conductivity OFF-state was not altered by successive stretching of 30% for 500 times. FIG. 12(d) shows the electrically programmed process of the WORM-type memory after stretching by 30% for 500 cycles. As seen in FIG. 12(d), even after 500 cycles of 30% strain, the electrical switching behavior operated normally from the OFF-state to the ON-state with a similar high ON/OFF ratio (˜10⁵) at a reading bias of 1 V compared with the unstrained device. These results suggest that the coded ON/OFF state can be correctly read out even after numerous cycles of elongation and contraction, demonstrating the durability of the stretchable memory for keeping the coded digital information. In addition, the stretchable organic memory was programmed normally, and its original electrical switching functions were retained even when the devices underwent numerous cycles of stretching, indicating their appropriateness for stretchable memory applications.

The transfer process presented here has several exceptional functions and features for generating stretchable organic memory. First, owing to the adhesive features and the ready-to-conduct graphene underlay without other supports, it is possible to transfer the memory devices onto stretchable electronics or circuitries while eliminating the solvent issue. In addition, using the transferrable organic memory with the graphene electrode may be beneficial for solving the handling and processing issue in the fabrication of organic memory devices on elastic polymeric substrates. Moreover, both of the organic materials and the bottom Cu/CVD-graphene are compatible with roll-to-roll fabricating processes. Consequently, the resultant stretchable organic memory may be beneficial for future industrial large-area printing and modular manufacture.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

What is claimed is:

1. A flexible and stretchable graphene film, comprising a graphene layer and a functional layer formed on the graphene layer.

2. The stretchable graphene film of claim 1, wherein the functional layer contains an insulating polymer and a conductive material.

3. The flexible and stretchable graphene film of claim 2, wherein the insulating polymer is at least one selected from of the group consisting of poly(methyl methacrylate), polyimide, polyacrylate, polyurethane, polyethylene terephthalate, polyethersulfone, polyether ether ketone, polycarbonate, poly(dimethylsiloxane), and a combination thereof.

4. The flexible and flexible and stretchable graphene film of claim 2, wherein the insulating polymer has a concentration in the range of 7 to 200 mg/ml.

5. The flexible and stretchable graphene film of claim 2, wherein the conductive material is at least one selected from the group consisting of polyaniline, polythiophene, polyethylenedioxythiopene (PEDOT), polyimide, polystyrenesulfonate (PSS), polypyrrole, polyacetylene, poly(p-phenylene), poly(p-phenylene sulfide), poly(p-phenylene vinylene), polythiophene poly(thienylene vinylene), carbon nanotube, metal nanoparticles, and a combination thereof.

6. The flexible and stretchable graphene film of claim 1, wherein the functional layer has a thickness of 1 to 400 nm.

7. The flexible and stretchable graphene film of claim 6, which is further transferred onto a substrate.

8. The flexible and stretchable graphene film of claim 7, wherein the substrate is an unconventional substrate.

9. The flexible and stretchable graphene film of claim 1, which further has a metal layer deposited on the functional layer.

10. The flexible and stretchable graphene film of claim 9, which exhibits a characteristic of a write-once-read-many-times (WORM) type memory or a re-writable type memory.

11. A method of producing a graphene film, comprising:
(a) providing a carrier and a graphene layer is formed on the surface of the carrier;
(b) forming a functional layer containing an insulating polymer and a conductive material on a top portion of the graphene layer, and
(c) removing the carrier to obtain the graphene film.

12. The method of claim 11, wherein the graphene layer is formed by chemical vapor deposition (CVD) method.

13. The method of claim 12, wherein the functional layer is formed by bar-coating, wire bar-coating, spin coating, dip coating, casting, micro gravure coating, gravure coating, roll coating, immersion coating, spray coating, screen printing, flexo printing, offset printing, or inkjet printing method.

14. The method of claim 13, wherein the insulating polymer is at least one selected from of the group consisting of poly(methyl methacrylate), polyimide, polyacrylate, polyurethane, polyethylene terephthalate, polyethersulfone, polyether ether ketone, polycarbonate, poly(dimethylsiloxane), and a combination thereof; and a conductive material is at least one selected from the group consisting of polyaniline, polythiophene, polyethylenedioxythiopene (PEDOT), polyimide, polystyrenesulfonate (PSS), polypyrrole, polyacetylene, poly(p-phenylene), poly(p-phenylene sulfide), poly(p-phenylene vinylene), polythiophene poly(thienylene vinylene), carbon nanotube, metal nanoparticles, and a combination thereof.

15. The method of claim 11, which further comprises the following steps:
(d) transferring the graphene film onto a pre-strained substrate; and
(e) releasing the pre-strained substrate.

16. The method of claim 15, wherein the substrate is an elastomer.

17. An apparatus, which has the flexible and stretchable graphene film of claim 1.
